(19) United States
(12) Patent Application Publication
(10) Pub. No.: US 2010/0059783 A1
(43) Pub. Date: Mar. 11, 2010

(54) Light Emitting Chip Package With Metal Leads For Enhanced Heat Dissipation

(76) Inventor: Harry Chandra, Mountain House, CA (US)

Correspondence Address: Harry Chandra, 654 Ellerbrook St., Mountain House, CA, 95391, US

(21) Appl. No.: 12/206,655

(22) Filed: Sep. 8, 2008

(51) Int. Cl. H01L 33/00

(52) U.S. Cl. 257/99; 257/E33.056

(57) ABSTRACT

A light emitting chip package includes a planar substrate, an LED die mounted on the substrate, and one or more relatively wide and thick metal leads to serve as a low thermal resistance path. The substrate comprises a chip mounting area and a wire bond area on a dielectric body. The LED die is seated on the chip mounting area and electrically connected to the wire bonding area. The metal leads are attached to the substrate and form terminals for external connection. At least one metal lead is connected to the chip mounting area to serve as a low thermal resistance path between the chip mounting area and an external heat sink.

### FIELD OF THE INVENTION

The present invention relates in general to a light emitting chip packages, and more particularly, to surface mountable light emitting diode (LED) packages with enhanced thermal dissipation.

### BACKGROUND OF THE INVENTION

Most light emitting diode (LED) devices converts less than half of the total electrical power into light. The remaining electrical energy is mostly turned into heat. The heat generated by the LED must be dissipated out as quickly as possible in order to prevent the LED from overheating. LED overheating can cause degradation in light output and life span. Preventing an LED die from overheating is one major challenge in designing a reliable LED package.

FIG. 1 shows a prior art LED package that has two relatively thin and long electrical leads 1 & 2. An LED die 3 is seated in an optical cavity formed at the top end of the lead 1. A bond wire 4 extends from the top of the LED 3 to an electrically opposite polarity lead 2. The entire structure is then encapsulated by a resin type encapsulating material 5 with only the electrical leads 1 and 2 partially projecting out of the enclosure. This type of package has a relatively low thermal performance because the thin and long electrical lead 1 has a relatively high thermal resistance. Therefore this type of package is not suitable for high power LED applications.

FIG. 2 is a cross sectional view of another prior art LED package having an insulating ceramic substrate. The ceramic substrate consists of two layers 10 and 11, which are normally formed by laminating a plurality of ceramic sheets. The lower layer 10 of the ceramic substrate supports a chip mounting platform 12, and a wire bonding pad 13; both are predetermined conductive patterns. An LED chip 14 is seated on the chip mounting area 12, and is surrounded by a cavity formed by the upper layer 11 of the ceramic substrate. A bond wire 15 extends from the top of the LED 14 to the wire bonding pad 13. In this type of package, heat generated by the LED is mainly conducted through the substrate body before being dissipated to an external heat sink (not shown). Therefore, thermal performance of these packages relies quite heavily on the thermal conductivity of the ceramic layer 10. However, most ceramic substrate materials are not very good thermal conductors, with their thermal conductivity values orders of magnitude below those of commonly used metals such as copper. It is very desirable to have an LED package that can offer a thermal path from a chip mounting area directly to an external heat sink without going through the substrate's body.

### SUMMARY OF THE INVENTION

The present invention is a light emitting chip package based on a planar substrate with metal leads for enhanced heat dissipation. The planar substrate comprises a chip mounting area and a wire bonding area on a dielectric body. A laminate substrate such as printed circuit board is ideal for most applications. An LED die is mounted on the chip mounting area, and wire bonded to the wire bonding area. A soft optically clear encapsulation material may be added to protect the LED die by dispensing, casting or molding. Enhanced thermal dissipation is achieved by employing one or more metal leads mounted on the perimeter of the substrate with at least one metal lead connected to the chip mounting area to serve as a low thermal resistance path between the chip mounting area and an external heat sink.

### BRIEF DESCRIPTION OF THE DRAWINGS

FIG. 1 illustrates a prior art LED package.

FIG. 2 illustrates another prior art LED package having a ceramic substrate.

FIG. 3 is a perspective view of a light emitting chip package with metal leads in an embodiment of the present invention.

FIG. 4 is a perspective view of a light emitting chip package having metal leads in an alternative embodiment of the present invention.

FIG. 5 is a cross sectional view of a light emitting chip package mounted on a heat sink, in another embodiment of the present invention.

FIGS. 6a and 6b are cross sectional views of a light emitting chip package with U shaped and L shaped metal leads in accordance with the present invention.

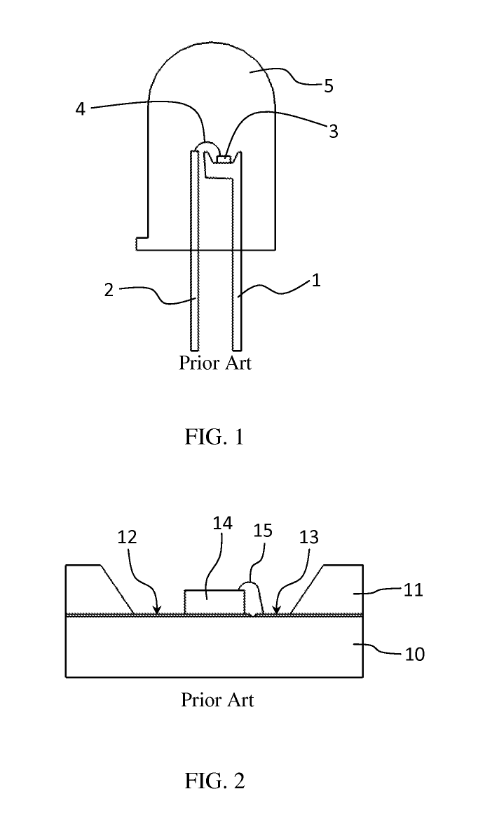

### DETAILED DESCRIPTION OF THE DRAWINGS

The present invention is described in one or more embodiments in the following description with reference to the Figures. It is to be understood that other embodiments would be evident based on the present disclosure, and that modifications and adaptations may be made without departing from the scope of the present invention. All matters shown in the accompanying drawings are to be interpreted in an illustrative and non-limiting sense.

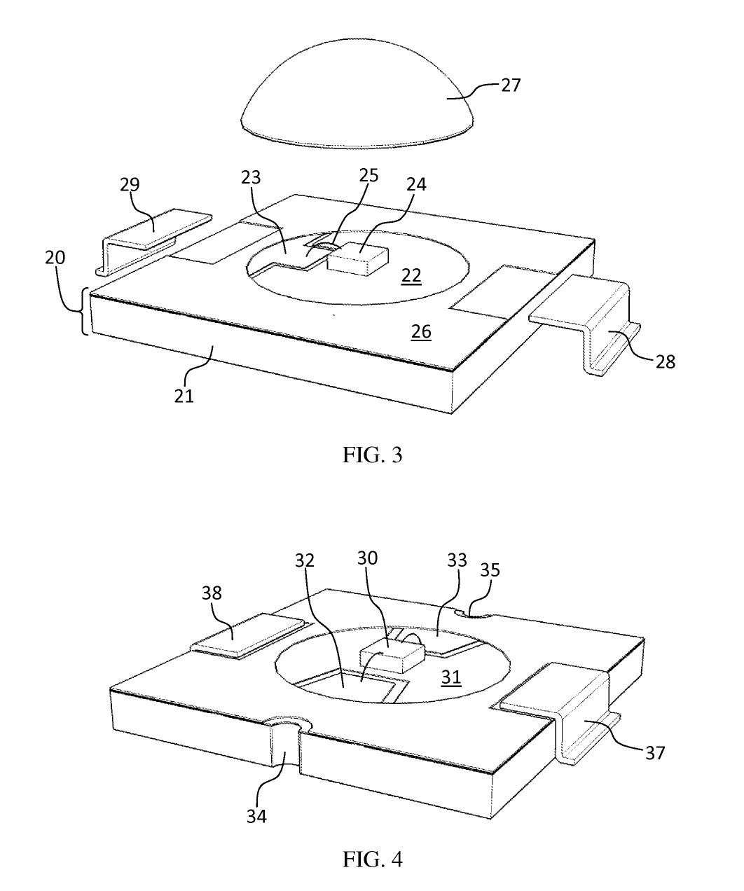

FIG. 3 is a perspective view of a light emitting chip assembly in accordance with the present invention. A substrate 20 includes a dielectric body 21, a chip-mounting area 22, a wire bonding area 23, and a solder mask layer 26. The chip mounting area 22 and the wire bonding area 23 are predetermined conductive patterns that are preferably made of copper (Cu). A laminate substrate, such as printed circuit board, or a ceramic substrate supports copper metallization and may be used as a substrate material. Unless an application requires the use of a ceramic substrate, a low cost printed circuit board substrate would be sufficient and ideal for many high power LED applications.

A light emitting diode (LED) chip 24 is seated on the chip mounting area 22. A bond wire 25 extends from the top of the LED chip to the wire bonding area 23. In this example, the top of the LED die represents one electrical polarity and the bottom of the LED represents another polarity, which is opposite to the top polarity. The wire bonding area 23 is, therefore, electrically opposite in polarity to the chip mounting area 22.

The chip mounting area 22 and the wire bonding area 23 extend outward to the edges of the substrate where solder mask 26 defines openings for mounting metal leads 28 and 29. After mounted to the substrate, one of the two metal leads 28 is connected to the chip mounting area 22, and the other metal lead 29 is connected to the wire bonding area 23. The two metal leads represent anode and cathode terminals of the package. The term “chip mounting area” refers to the entire conductive area that is connected to the chip mounting region; in other words, it is not limited to the location where the LED die is mounted. Likewise, the term “wire bonding area” refers to the entire conductive area that is connected to the wire bonding region.

An encapsulating material 27 may be applied to encase both the LED 24 and the bond wire 25, and may have a curved surface for optical purpose as illustrated in FIG. 3. The encapsulation can be achieved by various processes such as dispensing, molding, or casting. The encapsulating material 27 is preferably a soft material so that it provides a low stress protective coating over the LED and the bond wire. The encapsulating material should be optically clear and is preferably a high refractive index material, with refractive index around 1.5 or greater. Depending on applications, phosphor or other type of fillers may be added to the encapsulating material.

The two metal leads 28 and 29 in FIG. 3 may be soldered or attached by a conductive adhesive to the substrate 20. The preferred method is to have the metal leads soldered to the substrate for better thermal performance because a solder joint generally has a lower thermal resistance compared to a conductive adhesive joint. A variety of solder alloys may be used such as SnPb, AuSn, and SnAgCu. On the other hand, if a conductive adhesive is desired, a material with high thermal conductivity should be selected. A silver epoxy adhesive with high silver content may be one of such materials. A diamond-based thermal adhesive may also be used for applications where the metal leads are electrically isolated and serve only as a heat conducting path.

The metal leads are preferably made of a high thermal conducting metal. The preferred embodiment, in accordance with the present invention, employs copper (Cu) leads, due to copper's superior thermal conducting property. The copper leads may be plated with other metals, such as nickel (Ni) and gold (Au) or tin (Sn), to prevent copper oxidation and to facilitate bonding or solder joint. The metal leads may be manufactured from a copper sheet that may be stamped and formed into a desired shape. The metal leads 28 and 29 in FIG. 3 are shown in a relatively thick and wide design with respect to the package body; this is a preferred design in order to minimize thermal resistance. In general, thickness of 0.1 mm or greater is preferred. Finite element analysis may be employed to optimize a metal lead dimension.

The embodiment described above is for an LED package where the top side of the LED die represents one electrical polarity, and the bottom side represents the opposite polarity. There is another type of LED whose anode and cathode contacts are both located on the top side of the die, with the bottom side of the chip being electrically isolated from the top side. For this type of LED, other forms of electrical terminals may be used in conjunction with one or more metal leads. FIG. 4 is a perspective view of an LED package in an alternative embodiment of the present invention. An LED die 30 is seated on a chip mounting area 31. Since both anode and cathode bond pads are located on the top side, the LED is wire bonded to two wire bonding pads 32 and 33. The wire bonding pads 32 and 33 extend outward to the edge of the substrate and are terminated by electrical terminals 34 and 35. The electrical terminals in this example are represented each by a half cut plated-through hole. The chip mounting area 31 extends outward from the center of the substrate and is terminated by two metal leads 37 and 38. Since the bottom of the LED die is electrical isolated, the two metal leads are electrically isolated from the LED and serve solely as a low resistance heat path.

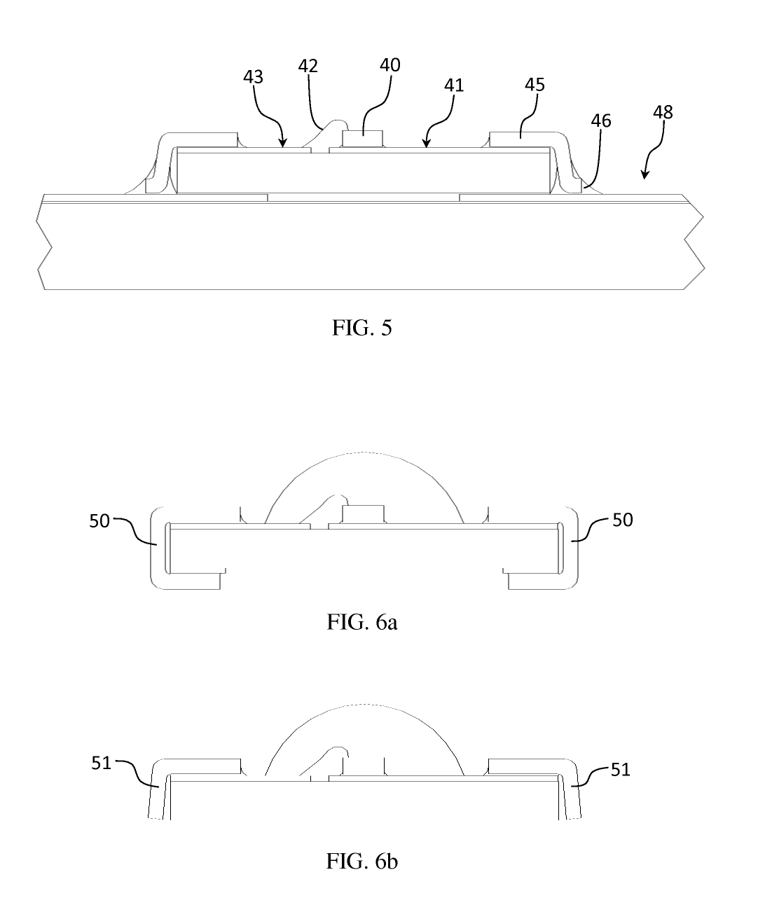

The primary purpose of a metal lead, in an embodiment of the present invention, is to provide a low thermal resistance path between an LED chip mounting area and an external heat sink. FIG. 5 is a cross sectional view of a light emitting chip package, in accordance with the present invention, that is mounted on a board having a metal base which also serves as a external heat sink. This cross sectional view illustrates thermal coupling between an LED die and an external heat sink through a metal lead. As seen in FIG. 5, an LED die 40 is seated on a chip mounting area 41 with a bond wire 42 extending from the top of the LED to a wire bonding area 43. The chip mounting area 41 extends outward to the edge of the substrate where it is terminated by a metal lead 45. The metal lead 45 is coupled to an external heat sink 48 through a solder joint 46. Heat generated by the LED 40 is first transferred to the chip mounting area 41. The heat is then quickly dissipated away by the metal lead 45, which serves as a low thermal resistance path, to the external heat sink 48.

There are many ways in which a metal lead may be used in a light emitting chip package or assembly in accordance with the present invention. Different combinations of shape, size, quantity, and arrangement may be employed, including features such as slots or cutouts. Metal leads can be straight or bent. FIG. 6a is a cross sectional view of an LED package illustrating U shaped metal leads 50, and FIG. 6b is a cross sectional view of an LED package illustrating L shaped metal leads 51.

In volume manufacturing, handling and processing multiple substrates in groups is preferred. Large panels, each containing multiple rows and columns of the substrates, can be handled more quickly and easily through the manufacturing lines than an individual substrate. After LED attach, wire bond, and encapsulation processes, the rows and columns of the substrates on each panel can then be separated into an individual substrate by a singulation process similar to silicon wafer dicing. After substrate singulation, metal leads can be mounted.

What has been described so far is an LED package where one or more metal leads are mounted to a package so that they are part of the package. It should be mentioned however that a metal lead may come as a separate piece and may be assembled to a package during a surface mount assembly. The surface mount assembly refers to an integration process where an LED package is surface mounted onto a board or a heat sink, along with possibly other component(s).

One or more embodiments of an LED package with metal leads for enhanced heat dissipation, in accordance with the present invention, have been discussed. One principle aspect of the present invention is that it facilitates using a low cost laminate substrate such as printed circuit board (PCB) for high power LED packages requiring enhanced thermal dissipation.

While one or more embodiments of the present invention have been illustrated in some detail, those skilled in the art will appreciate that various modifications, alternatives, variations, and adaptations are possible without departing from the scope of the present invention as set forth in the following claims.

What is claimed is:

1. A light emitting chip package comprising:
a substrate having at least a chip mounting area and a wire bond area on a dielectric body;
at least one light emitting chip seated on the chip mounting area and electrically connected to the wire bond area; and
one or more metal leads attached to the substrate and connected at least to the chip mounting area.

2. The light emitting chip package of claim 1, wherein the substrate is selected from the group consisting of printed circuit board and ceramics.

3. The light emitting chip package of claim 1, wherein the one or more metal leads are soldered or attached by a conductive adhesive to the substrate.

4. The light emitting chip package of claim 1, further comprising an encapsulating material over the light emitting chip.

5. A light emitting chip assembly comprising:
a light emitting chip package having a planar substrate with access pads;
a board for mounting the light emitting chip package; and
one or more metal leads mounted to the access pads of the light emitting chip package and coupled to the board.

6. The assembly of claim 5, wherein the light emitting chip package comprises at least one LED chip.

7. The assembly of claim 5, wherein the one or more metal leads are soldered or attached by a conductive adhesive to the light emitting chip package and the board.

8. The assembly of claim 5, wherein the board is selected from the group consisting of printed circuit board, metal-core printed circuit board.

9. The assembly of claim 5, wherein the light emitting chip package further comprising an encapsulating material over the light emitting chip.
